(19) United States
(12) Patent Application Publication
(10) Pub. No.: US 2003/0054591 A1
(43) Pub. Date: Mar. 20, 2003

(54) Semiconductor device, and method of manufacturing the semiconductor device

(75) Inventors: Shunichi Abe, Tokyo (JP); Tetsuya Uebayashi, Tokyo (JP); Naoki Izumi, Tokyo (JP); Akira Yamazaki, Tokyo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/091,324

(22) Filed: Mar. 6, 2002

(30) Foreign Application Priority Data
Sep. 20, 2001 (JP) 2001-287395

(51) Int. Cl. H01L 21/44; H01L 21/48; H01L 21/50

(52) U.S. Cl. 438/111; 438/123; 257/666

(57) ABSTRACT

The semiconductor device is manufactured as follows. That is, after the die pad section, on which the semiconductor chip is mounted, the inner lead section and at least a part of the outer lead section are arranged in the cavity of the metal mold on the lead frame. Moreover, the sealing resin is filled into the cavity of the metal mold and hardened therein. Moreover, the sealing resin located on a surface layer region of the outer lead section of the lead frame removed.

### FIELD OF THE INVENTION

The present invention relates to a semiconductor device and a method of manufacturing the semiconductor device. Particularly, this invention relates a method of manufacturing a resin sealed semiconductor device sealing a semiconductor chip on a lead frame and a connecting section connecting the semiconductor chip to the lead frame by a resin.

### BACKGROUND OF THE INVENTION

There is known hitherto a semiconductor device wherein a semiconductor chip mounted on a lead frame and a connecting section (“inner bonding section”) connecting the semiconductor chip to the lead frame are sealed with a resin. In the semiconductor device of this type, the semiconductor chip and the inner bonding section are covered with the sealing resin and it is, therefore, possible to prevent the influence of temperature, humidity, impact and pressure on the semiconductor chip and the inner bonding section.

FIG. 16A to FIG. 16D sequentially show a method of manufacturing the conventional semiconductor device. According to this method of manufacturing the semiconductor device, first, as shown in FIG. 16A and FIG. 16B, a semiconductor chip 3 is mounted on each die pad section 2 of a lead frame 1, the inner lead of the lead frame 1 is connected to the bonding pad of the semiconductor chip 3 by a conductor such as a wire (inner bonding) and then the lead frame 1 is set to a metal mold 4.

The metal mold 4 is constituted out of an upper mold 4a and a lower mold 4b arranged to be able to be opened and closed. The upper mold 4a and lower mold 4b are provided with cavity constituent sections 4a₁ and 4b₁ on their respective surfaces facing each other. Each of the cavity constituent sections 4a₁ and 4b₁ is constituted to define a cavity 5 large enough to contain the semiconductor chip 3 and the inner bonding section stated above if the upper mold 4a and the lower mold 4b are closed relative to each other. As shown in FIG. 16C, therefore, the die pad section 2 on which the semiconductor chip 3 is mounted and the inner bonding section are contained in the cavity 5 on the lead frame 1 while the sections 6 which become outer leads are located outside of the cavity 5. In this state, if a molten sealing resin 7 is filled and hardened into each cavity 5, it is possible to manufacture a semiconductor device 8 having desired regions sealed with the sealing resin 7 as shown in FIG. 16D.

The sealing resin 7 of the semiconductor device 8 is shaped according to each cavity 5 provided in the metal mold 4. As a result, if the shape of the cavity of the metal mold 4 is not changed, the width, the length or the outside shape of the sealing resin 7 in the semiconductor device 8 cannot be changed even with the thickness of the resin left unchanged. Therefore, it is necessary to design and manufacture a new metal mold 4, making it disadvantageously difficult to promptly deal with such demand and disadvantageously pushing up the manufacturing cost of the semiconductor device 8. Also, if semiconductor devices different in the width or length of a sealing resin or in outside shape thereof are to be manufactured in succession, it is indispensable to change the metal mold 4 in respective setup operations, which disadvantageously prevents the improvement of manufacturing efficiency.

### SUMMARY OF THE INVENTION

It is an object of the present invention to provide a semiconductor device and a method of manufacturing the semiconductor device capable of dealing with the change of the width or the length of a sealing resin or the change of the outside shape of the sealing resin, capable of reducing manufacturing cost and capable of improving manufacturing efficiency.

The method of manufacturing the semiconductor device according to one aspect of the present invention includes arranging at least a part of a portion of a lead frame that is to be sealed with a resin, and a portion that is to become an outer lead, respectively, in a cavity of a metal mold; filling a sealing resin into the cavity of said metal mold, and hardening the sealing resin; and removing a member covering a surface layer region of the section, to become the outer lead, of said lead frame.

The method of manufacturing the semiconductor device according to another aspect of the present invention includes fixedly attaching removable members to both sides of a section, to become an outer lead, of a lead frame; arranging a section, to be sealed with a resin, of said lead frame including said removable members in a cavity of a metal mold; filling a sealing resin into the cavity of said metal mold, and hardening the sealing resin; forming a groove ranging from a surface of said sealing resin to edges of said removable members; and removing a member covering the section to become said outer lead, with the portion in which said groove is formed set as a boundary.

The semiconductor device according to still another aspect of the present invention is manufactured using any one or a combination of the methods of manufacturing described above.

Other objects and features of this invention will become apparent from the following description with reference to the accompanying drawings.

### BRIEF DESCRIPTION OF THE DRAWINGS

FIG. 1A and FIG. 1B show a semiconductor device manufacturing method in the first embodiment according to the present invention, where FIG. 1A is a perspective view of a lead frame and FIG. 1B is a cross-sectional side view of the lead frame;

FIG. 2 is a cross-sectional side view showing a state in which the lead frame shown in FIG. 1 is arranged in the cavity of a metal mold;

FIG. 3 is a cross-sectional side view showing a state in which the lead frame is separated from the metal mold shown in FIG. 2 after a sealing resin is filled into the metal mold shown in FIG. 2 and hardened therein;

FIG. 4 is a cross-sectional side view showing a state in which kerfs are formed in the sealing resin of the lead frame shown in FIG. 3;

FIG. 5 is a cross-sectional side view showing a state in which kerfs are further formed in the sealing resin of the lead frame shown in FIG. 4;

FIG. 6 is a cross-sectional side view showing a state in which removal tapes are bonded to the sealing resin of the lead frame shown in FIG. 5;

FIG. 7 is a cross-sectional side view showing a state in which unnecessary parts are removed from the sealing resin of the lead frame shown in FIG. 6;

FIG. 8A and FIG. 8B show a method of manufacturing the semiconductor device in the second embodiment according to the present invention, where FIG. 8A is a perspective view of a lead frame and FIG. 8B is a cross-sectional side view of the lead frame;

FIG. 9 is a cross-sectional side view showing a state in which the lead frame shown in FIG. 8 is arranged in the cavity of a metal mold;

FIG. 10 is a cross-sectional side view showing a state in which the lead frame is separated from the metal mold shown in FIG. 9 after a sealing resin is filled into the metal mold and hardened therein;

FIG. 11 is a cross-sectional side view showing a state in which kerfs are formed in the sealing resin of the lead frame shown in FIG. 10;

FIG. 12 is a cross-sectional side view showing a state in which kerfs are further formed in the sealing resin of the lead frame shown in FIG. 11;

FIG. 13 is a cross-sectional side view showing a state in which removal tapes are bonded to the sealing resin of the lead frame shown in FIG. 12;

FIG. 14 is a cross-sectional side view showing a state in which unnecessary parts are removed from the sealing resin of the lead frame shown in FIG. 13;

FIG. 15A and FIG. 15B show a method of manufacturing the semiconductor device in the third embodiment according to the present invention, where FIG. 15A is a perspective view of a lead frame and FIG. 15B is a cross-sectional side view of the lead frame; and

FIG. 16A and FIG. 16B show a conventional method of manufacturing the semiconductor device, where FIG. 16A is a perspective view of a lead frame, FIG. 16B is a cross-sectional side view of the lead frame, FIG. 16C is a cross-sectional side view showing a sate in which the lead frame shown in FIG. 16B is arranged in the cavity of a metal mold, and FIG. 16D is a cross-sectional side view showing a state in which the lead frame is separated from the metal mold shown in FIG. 16C after the sealing resin is filled into the metal mold and hardened therein.

### DETAILED DESCRIPTIONS

Embodiments of the semiconductor device and the method of manufacturing the semiconductor device according to the present invention will be described hereinafter in detail with reference to the accompanying drawings.

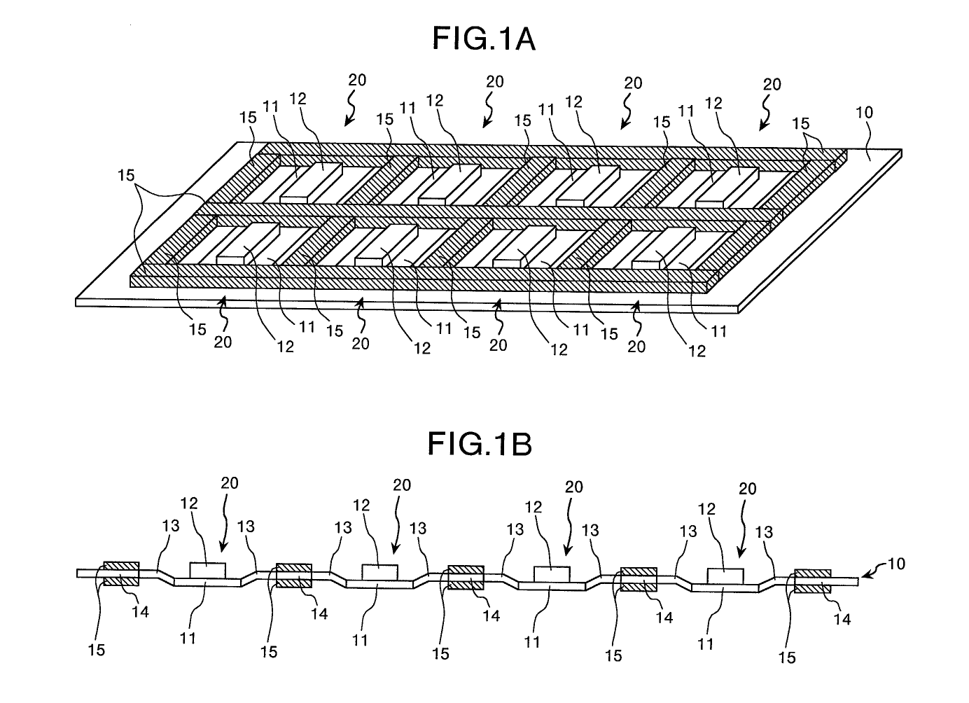

FIG. 1A to FIG. 7B sequentially show the method of manufacturing the semiconductor device according to the first embodiment of the present invention. Semiconductor devices to be manufactured in the first embodiment are constituted as, for example, a TSO (Tin Small Outline Package), so that semiconductor chips mounted on the die pad sections of a lead frame and the connection sections (to be simply referred to as “inner bonding sections” hereinafter) for connecting the semiconductor chips to the lead frame are sealed with a resin and that the outer leads of the lead frame are extended outside of the sealing resin. As shown in FIG. 1A, a lead frame 10 has a plurality of die pad sections 11 horizontally and vertically so as to enable constituting a plurality of semiconductor devices together and sections to become inner leads (to be simply referred to as “inner lead sections 13” hereinafter) and sections to become outer leads (to be simply referred to as “outer lead sections 14” hereinafter) are provided around the respective die pad sections 11. In the following description, parts necessary to constitute one semiconductor device on the lead frame 10, i.e., the die pad section 11, the inner lead sections 13 and the outer lead sections 14 will be generally referred to as a semiconductor device constituent section 20.

As shown in FIG. 1A and FIG. 1B, a semiconductor chip 12 is mounted on a die pad section 11 on each semiconductor device constituent section 20 of the lead frame 10, the inner lead section 13 on the lead frame 10 is connected to the bonding pad (not shown) of each semiconductor chip 12 by a conductor such as a wire and bonding sheets 15 are bonded to parts around the die pad section 11, i.e., the both sides of the outer lead sections 14 on each semiconductor device constituent section 20 of the lead frame 10, respectively.

Each of the bonding sheets 15 applied herein has a sheet as a base material coated with an adhesive having removability from the lead frame 10. The bonding sheet 15 is band-shaped to have a width equal to the length of the outer lead section 14. Heat resistance to prevent the sheet serving as the base material from being fused or lost when filled with a molten resin to be described later is secured for the sheet.

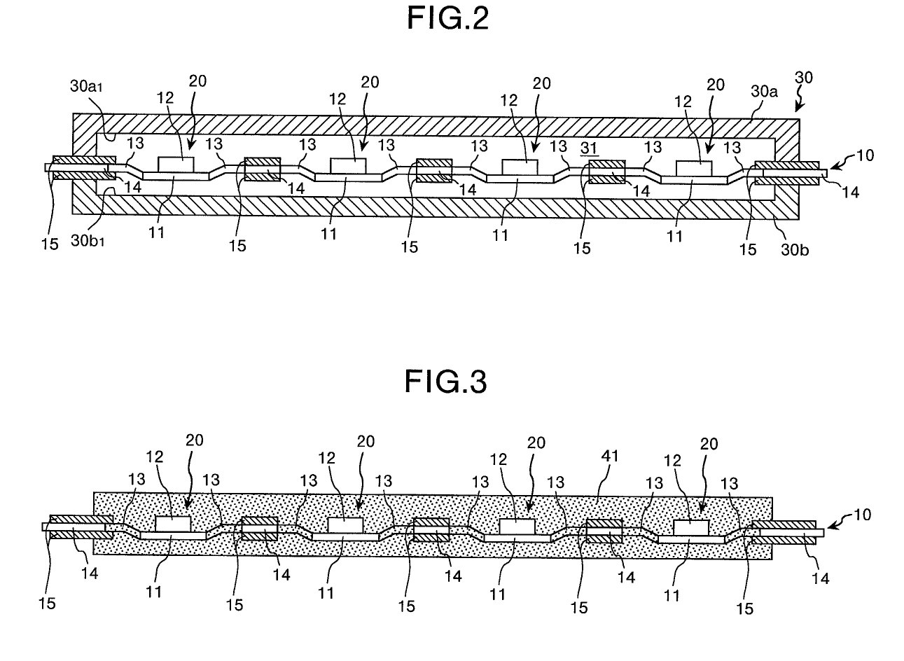

As shown in FIG. 2, the lead frame 10 stated above is arranged in the cavity 31 of a metal mold 30. The metal mold 30 applied herein has an upper-mold 30a and a lower mold 30b provided to be able to be opened and close relative to each other. These upper mold 30a and lower mold 30b are respectively provided with cavity constituent sections 30a₁ and 30b₁ facing each other. Each of the cavity constituent sections 30a₁ and 30b₁ has a width and a length to allow containing the die pad sections 11 on which the semiconductor chips 12 are mounted, the inner lead sections 13 and at least a part of the sections to which the bonding sheets 15 are bonded in all the semiconductor device constituent sections 20 provided on the lead frame 10 if the upper mold 30a and the lower mold 30b are closed relative to each other. In addition, the cavity constituent sections 30a₁ and 30b₁ are constituted to define only one cavity 31 having a height equal to the thickness of the sealing resin 41 on a semiconductor device 40 to be manufactured.

In this state, the cavity 31 of the metal mold 30 is filled with a sealing resin 41 in a molten state and the sealing resin 41 is separated from the metal mold 30 after the passage of a predetermined pressure maintaining and cooling period of time. In this state, as shown in FIG. 3, all the semiconductor device constituent sections 20 provided on the lead frame 10 are sealed with the common sealing resin 41.

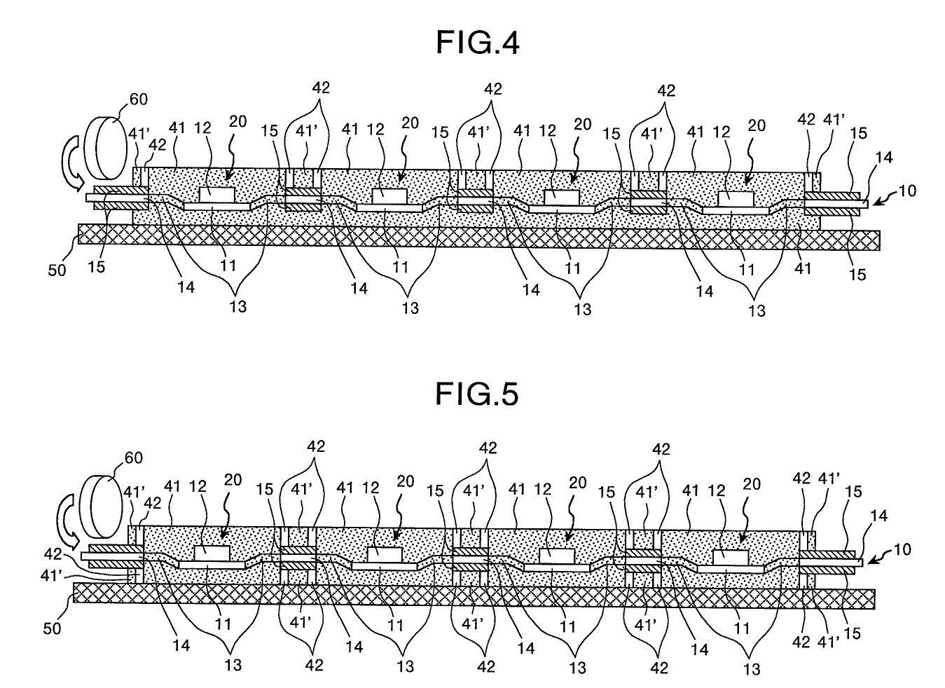

Next, as shown in FIG. 4, a support tape 50 is bonded to one side of the sealing resin 41 to thereby fix the lead frame 10. Further, in this state, a cutting machine such as a dicer is used to sequentially form kerfs 42 on the other side of the sealing resin 41 by a blade 60 rotating at high speed. At this moment, the blade 60 of the cutting machine is set to be directed toward the edges of the bonding sheet 15 bonded to the lead frame 10 and to progress along the outside shape of the sealing resin 41 to be formed in the semiconductor device 40. Also the depth of each kerf 42 cut by the blade 60 is set to reach the surface of the bonding sheet 15 but not reach the surface of the lead frame 10.

Thereafter, as shown in FIG. 5, the lead frame 10 is inverted, the support tape 50 on one side of the sealing resin 41 is removed and a support tape 50 is bonded to the other side of the sealing resin 41 to thereby fix the lead frame 10. Further, in this state, kerfs 42 are sequentially formed on one side of the sealing resin 41 by the blade 60 as in the case of the above.

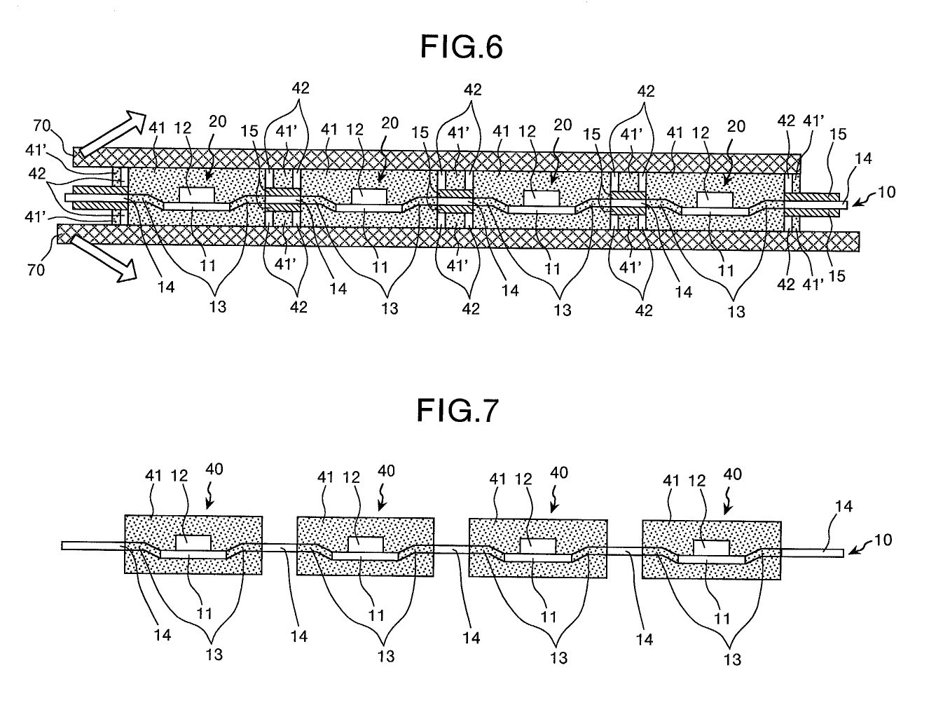

As a result, sealing resins 41′ located on the surface layer regions of the outer lead sections 14 are separated from the sealing resin 41 of the semiconductor devices 40 on the lead frame by the kerfs 42 formed on the both sides of the sealing resin 41. Accordingly, after the support tape 50 is removed from the other side of the sealing resin 41, if removal tapes 70 are bonded to the both sides of the sealing resin 41, respectively and the removal tapes 70 thus bonded are removed from the sealing resin 41 as show in FIG. 6, then the sealing resins 41′ can be easily removed together with the bonding sheets 15 as members located on the surface layer regions of the outer lead sections 14 as shown in FIG. 7.

Next, if the outer lead sections 14 of the adjacently provided semiconductor devices 40 are cut off, it is possible to obtain desired semiconductor devices 40 sealed with the sealing resin 41 having the desired width and length and having the desired outside shape. The semiconductor devices 40 is finally completed through a package plating and lead processing step.

According to the method of the first embodiment, as already described above, by temporarily sealing the outer lead sections 14 which do not require the sealing resin 41 with the sealing resin 41 and then removing the sealing resins 41′ located on the surface layer regions of the outer lead sections 14, the width, length and outside shape of the sealing resin 41 on the semiconductor devices 40 are specified. It is, therefore, possible to use the common metal mold 30 even if semiconductor devices 40 different in the width, length and/or outside shape of the sealing resin 41 are to be manufactured. That is, even after the sealing resin 41 is separated from the common metal mold 30, it is possible to obtain semiconductor devices 40 sealed with the sealing resin 41 having a width and a length changed and a desired outside shape by forming kerfs 42 along the changed width and length or the outside shape of the sealing resin 41 and removing the sealing resins 41′ located on the surface layer regions of the outer lead sections 14. Consequently, according to the manufacturing method stated above, even if the width, length and/or outside shape of the sealing resin 41 are changed, there is no need to design and manufacture a new metal mold 30, making it possible to promptly deal with such a change and to prevent the increase of manufacturing cost. Moreover, since there is no need to change the metal mold 30, no setup operation is required to continuously manufacture semiconductor devices different in the width, length and/or outside shape of the sealing resin 41, thereby making it possible to improve manufacturing efficiency.

Additionally, since the bonding sheets 15 are interposed between the sealing resins 41′ to be removed and the outer lead sections 14, it is possible to prevent the outer lead sections 14 and the sealing resins 41′ from being fixedly coupled to each other when hardening the sealing resin 41, making it possible to facilitate the removal operation of the sealing resins 41′.

Moreover, since the bonding sheets 15 having removability from the outer lead sections 14 are used, it is possible to prevent the positional error of the bonding sheets 15 relative to the outer lead sections 14 if the sealing resin 41 is filled into the metal mold 30 and it is possible to easily remove the bonding sheets 15 from the outer lead sections 14 if removing the sealing resins 41′. It is, therefore, possible to prevent the removal operation of the sealing resins 41′ from becoming complex and to prevent the width, length and/or outside shape of the sealing resin 41 from becoming uneven on the semiconductor devices.

In the first embodiment, the bonding sheets 15 are bonded to the outer lead sections 14 of the lead frame 10. In the second embodiment described in detail below, by contrast, spacers 80 instead of the bonding sheets 15 are employed.

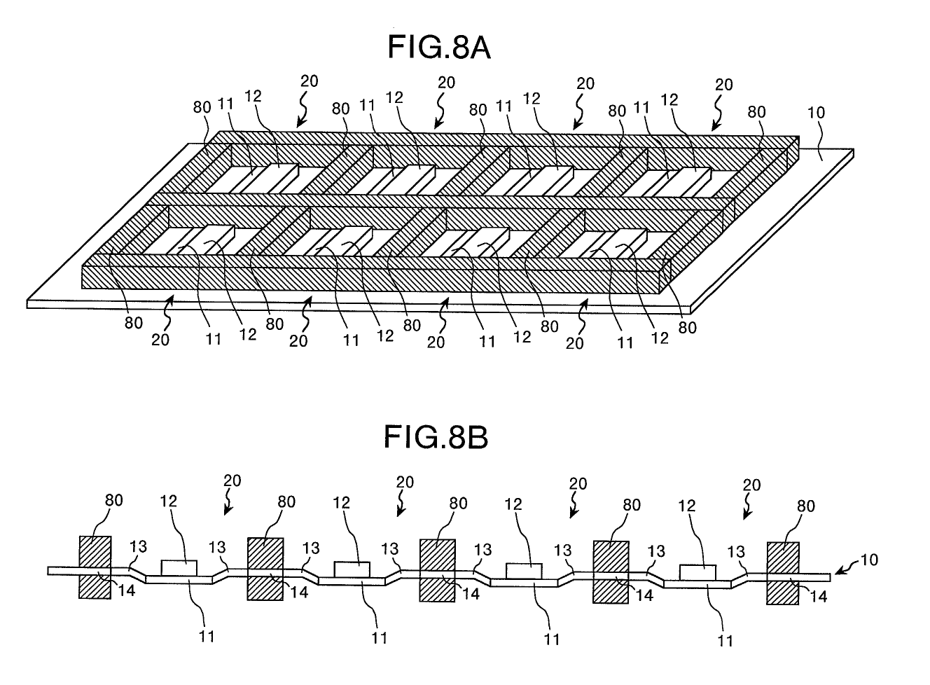

FIG. 8A to FIG. 14 sequentially show a method of manufacturing the semiconductor device in the second embodiment according to the present invention. Similarly to the semiconductor devices shown in the first embodiment 1, semiconductor devices to be manufactured in the second embodiments are TSOP type semiconductor devices constituted so that semiconductor chips mounted on the die pad sections of a lead frame and inner lead sections are sealed with a resin and that the outer leads of the lead frame are extended to the outside of the sealing resin. As shown in FIG. 8A, a plurality of die pad sections 11 are provided horizontally and vertically and the inner lead sections 13 and the outer lead sections 14 are provided around the respective die pad sections 11 so as to constitute a plurality of semiconductor devices together, as in the case of the first embodiment.

As shown in FIG. 8A and FIG. 8B, according to the manufacturing method in the second embodiment, first, the semiconductor chip 12 is mounted on the die pad section 11 on each semiconductor device constituent section 20 on the lead frame 10, the inner lead section 13 on the lead frame 10 is connected to the bonding pad (not shown) of each semiconductor chip 12 by a conductor such as a wire and spacers 80 are fixedly attached to the both sides of the outer lead section 14 on each semiconductor device constituent section 20 of the lead frame 10, respectively.

Each of the spacers 80 applied herein has a cross-sectional surface of a rectangular cylinder shape and is made of a metal material or a resin material for which heat resistance to prevent the spacer 80 from being fused or lost when filled with a molten resin to be described later. Each spacer 80 has preferably dimensions so that the total thickness of the spacers 80 fixed attached to the both sides of each outer lead section 14, respectively, is equal to the thickness of the sealing resin 41 on each semiconductor device 40 to be manufactured. In view of its removability, it is preferable to select a material having low adhesion to the outer lead section 14 of the lead frame 10 as that of the spacer 80. It is noted that even if a material having high adhesion to the outer lead section 14 of the lead frame 10 is selected, good removability can be secured for the material by subjecting a surface treatment to the surface of the spacer 80 on which the spacer 80 contacts with the outer lead section 14 to lower the adhesion. To make the lead frame 10 hold the spacers 80, if the spacers 80 are metal spacers, the spacers 80 may be welded to the lead frame 10 outside of the regions of the semiconductor device constituent sections 20 by welding means such as welding. If the spacers 80 are resin spacers, the spacers 80 may be bonded to the lead frame 10 outside of the regions of the semiconductor device constituent sections 20 by bonding means such as an adhesive.

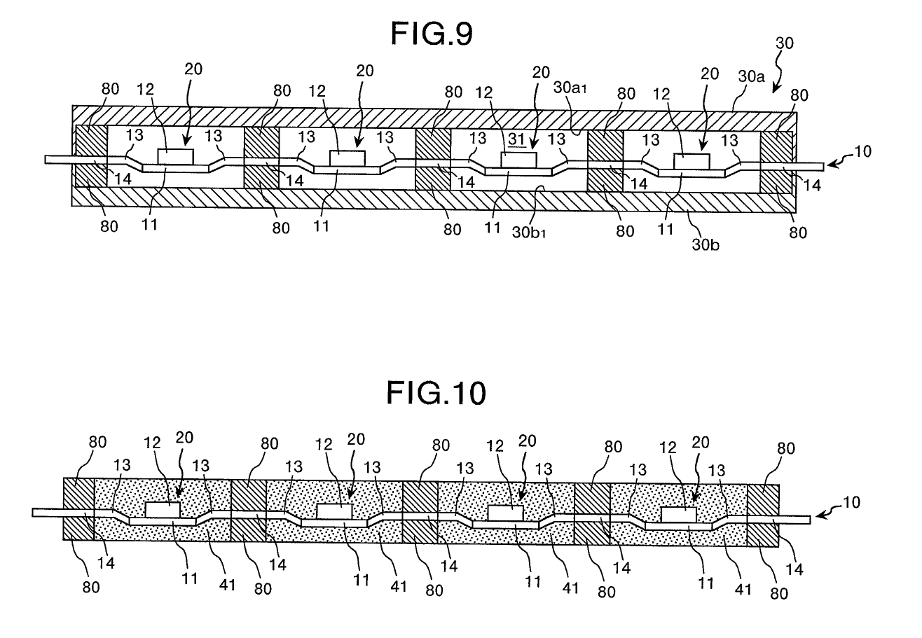

Next, as shown in FIG. 9 and FIG. 10, the lead frame 10 stated above is arranged in the cavity 31 of a metal mold 30, a sealing resin 41 in a molten state is filled into the cavity 31 of the metal mold 30 and separated from the metal mold 30 after the passage of a predetermined pressure maintaining and cooling period of time. The metal mold 30 applied herein has the same configuration as that of the metal mold 30 shown in the first embodiment. Namely, the metal mold 30 having an upper mold 30a and a lower mold 30b respectively provided with cavity constituent sections 30a₁ and 30b₁ which face each other and which can be opened and closed relative to each other is employed herein. The cavity constituent sections 30a₁ and 30b₁ are provided at the upper die 30a and the lower die 30b, respectively, as in the case of those in the first embodiment. Namely, each of the cavity constituent sections 30a₁ and 30b₁ has a width and a length to allow containing the die pad sections 11 on which the semiconductor chips 12 are mounted, the inner lead sections 13 and at least a part of the sections to which the bonding sheets 15 are bonded in all the semiconductor device constituent sections 20 provided on the lead frame 10 if the upper mold 30a and the lower mold 30b are closed relative to each other. In addition, the cavity constituent sections 30a₁ and 30b₁ are constituted to define only one cavity 31 having a height equal to the thickness of the sealing resin 41 on a semiconductor device 40 to be manufactured.

The spacers 80 having a total thickness which is equal to the thickness of the sealing resin 41 on a semiconductor device 40 to be manufactured, are fixedly attached to the both sides of each outer lead section 14 on the lead frame 10, respectively. Accordingly, if the upper mold 30a and the lower mold 30b are closed in a state in which the lead frame 10 is arranged in the cavity 31 of the metal mold 30, the outer surfaces of the spacers 80 are abutted on the inner wall surfaces of the cavity 31 to thereby support the outer lead sections 14 of the lead frame 10 as clearly shown in FIG. 9. As a result, even if the cavity 32 of the metal mold 30 is filled with the sealing resin 41 in a molten state, there is no fear that the outer lead sections 14 are vertically shifted in the cavity 31, thereby making it possible to seal the semiconductor chips 12 and the inner lead sections 13 on all the semiconductor device constituent sections 20 at the common positions of the sealing resin 41, respectively.

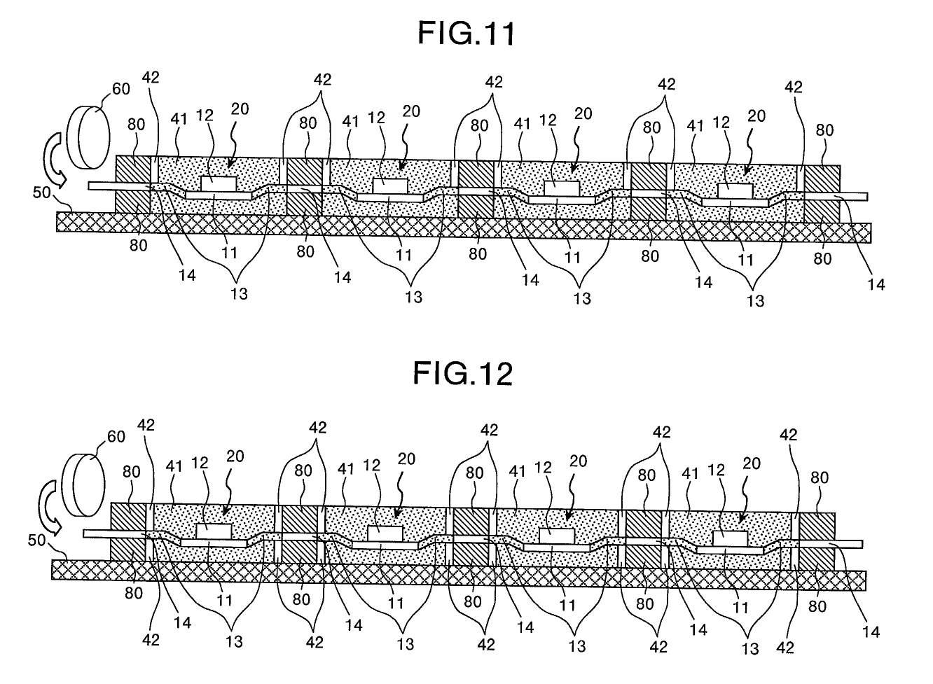

Thereafter, in the same manner as in the first embodiment, support tapes 50 are bonded alternately on the surfaces of the sealing resin 41 to thereby fix the lead frame 10. In this state, kerfs 42 are sequentially formed on the both sides of the sealing resin 41 by the blade 60 of a cutting machine (see FIG. 11 and FIG. 12). At this moment, the blade 60 of the cutting machine is not necessarily progressed along the edges of the spacers 80 fixedly attached to the lead frame 10. It suffices that the blade 60 is progressed along the outside shape of the sealing resin 41 to be constituted on the semiconductor device 40 and reaches the edges of the spacers 80 in the portions proximate to the fixedly attached sections of spacers 80 to the lead frame 10. The depth of each kerf 42 cut by the blade 60 is set not to reach the surface of the lead frame 10 as in the case of the first embodiment.

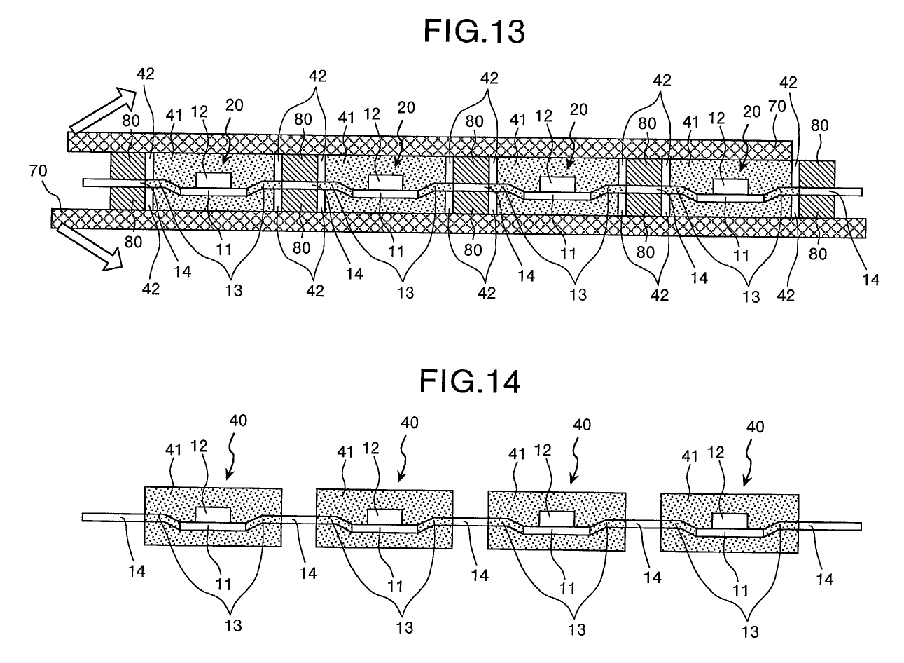

As a result, members located on the surface layer regions of the outer lead sections 14 of the lead frame 10 are separated from the sealing resin 41 of the semiconductor devices 40 (in the example shown, only the spacers 80 are separated) by the kerfs 42 formed on the both sides of the sealing resin 41. As shown in, for example, FIG. 13, if removal tapes 70 are bonded to the both sides of the sealing resin 41, respectively and the removal tapes 70 thus bonded are removed from the sealing resin 41, then the spacers 80 (or spacers 80 and sealing resins 411) as the members located on the surface layer regions of the outer lead sections 14 can be removed as shown in FIG. 14. Besides, by cutting off the outer lead sections of the adjacently provided semiconductor devices 40, it is possible to obtain desired semiconductor devices 40 sealed with the sealing resin 41 having the desired width and length and the desired outside shape.

According to the method of the second embodiment, as already stated above, by sealing even the outer lead sections 14 which do not require the sealing resin 41 with the sealing resin 41 and then removing the spacers 80 (or spacers 80 and sealing resins 41′) located on the surface layer regions of the outer lead sections 14, the width, length and outside shape of the sealing resin 41 on the semiconductor devices 40 are specified. It is, therefore, possible to use the common metal mold 30 even if semiconductor devices 40 different in the width, length and/or outside shape of the sealing resin 41 are to be manufactured. That is, even after the sealing resin 41 is separated from the common metal mold 30, it is possible to obtain semiconductor devices 40 sealed with the sealing resin 41 having a width and a length changed and a desired outside shape by forming kerfs 42 along the changed width and length or the outside shape of the sealing resin 41 and removing the spacers 80 (or spacers 80 and sealing resins 41′) located on the surface layer regions of the outer lead sections 14. Consequently, even if the width, length and/or outside shape of the sealing resin 41 are changed, there is no need to design and manufacture a new metal mold 30, making it possible to promptly deal with such a change and to prevent the increase of manufacturing cost. Moreover, since there is no need to change the metal mold 30, no setup operation is required to continuously manufacture semiconductor devices different in the width, length and/or outside shape of the sealing resin 41, thereby making it possible to improve manufacturing efficiency.

Additionally, since the spacers 80 to be removed are simply, fixedly attached to the outer lead sections 14, it is possible to easily perform the removal operation of the spacers 80. In the example shown in FIG. 8A to 14, only the spacers 80 are removed. It is, however, sometimes necessary to remove not only the spacers 80 but also sealing resins 41′ depending on the positions and angles of the kerfs 42. In that case, however, since the spacers 80 are interposed between the sealing resins 411 to be removed and the outer lead sections 14 in advance, it is possible to prevent the outer lead sections 14 and the sealing resins 41′ from being fixedly coupled to each other when hardening the sealing resin 41, making it possible to facilitate the removal operation of the spacers 80 and the sealing resins 41′. In the second embodiment, even in the latter case, since the quantity of the sealing resins 41′ to be removed can be reduced (to zero in the example shown) by the presence of the spacers 80, it is possible to improve operation efficiency and to further reduce manufacturing cost.

Moreover, the spacers 80 are constituted so that the total thickness of the spacers 80 fixedly attached to the both sides of each outer lead section 14, respectively, is equal to the thickness of the sealing resin 41 on the semiconductor device 40 to be manufactured. If the lead frame 10 is arranged in the cavity 31 of the metal mold 30, the individual outer surfaces of the spacers 80 are abutted on the inner wall surfaces of the cavity 31, respectively. Due to this, even if the cavity 31 of the metal mold 30 is filled with the sealing resin 41 in a molten state, there is no fear that the outer lead sections 14 are vertically shifted in the cavity 31. As a result, it is possible to seal the semiconductor chips 12 and the inner lead sections 13 on all the semiconductor device constituent sections 20 at the common positions of the sealing resin 41, respectively and to, therefore, uniform the various performances of the semiconductor devices 40 such as heat resistance, moisture resistance, impact resistance and pressure resistance.

In the second embodiment, the spacers 80 are fixedly attached to the outer lead sections 14 of the lead frame 10. In the third embodiment described in detail below, by contrast, bonding sheets 15 are interposed between each outer lead section 14 of the lead frame 10 and the spacers 80.

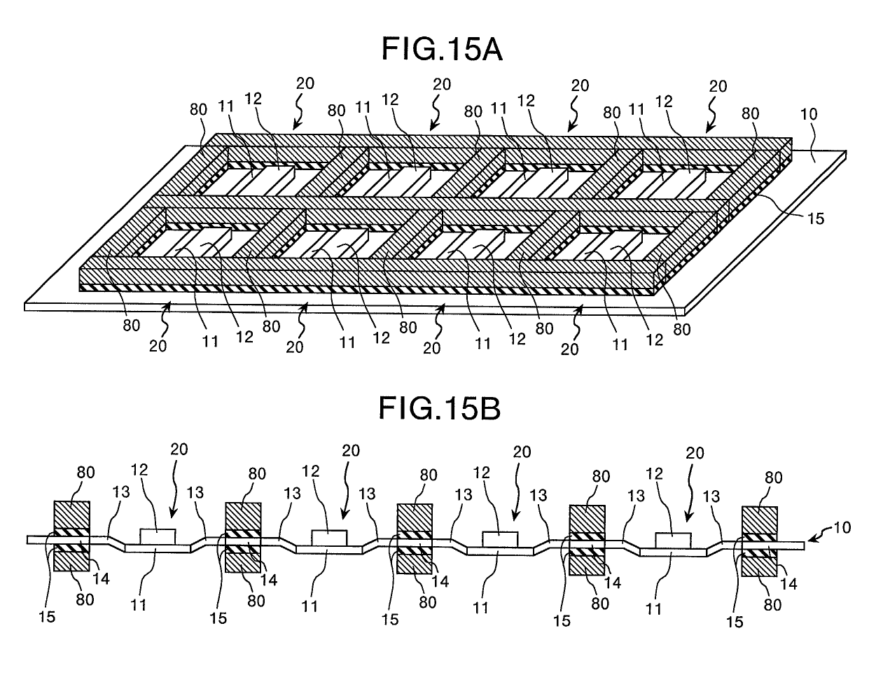

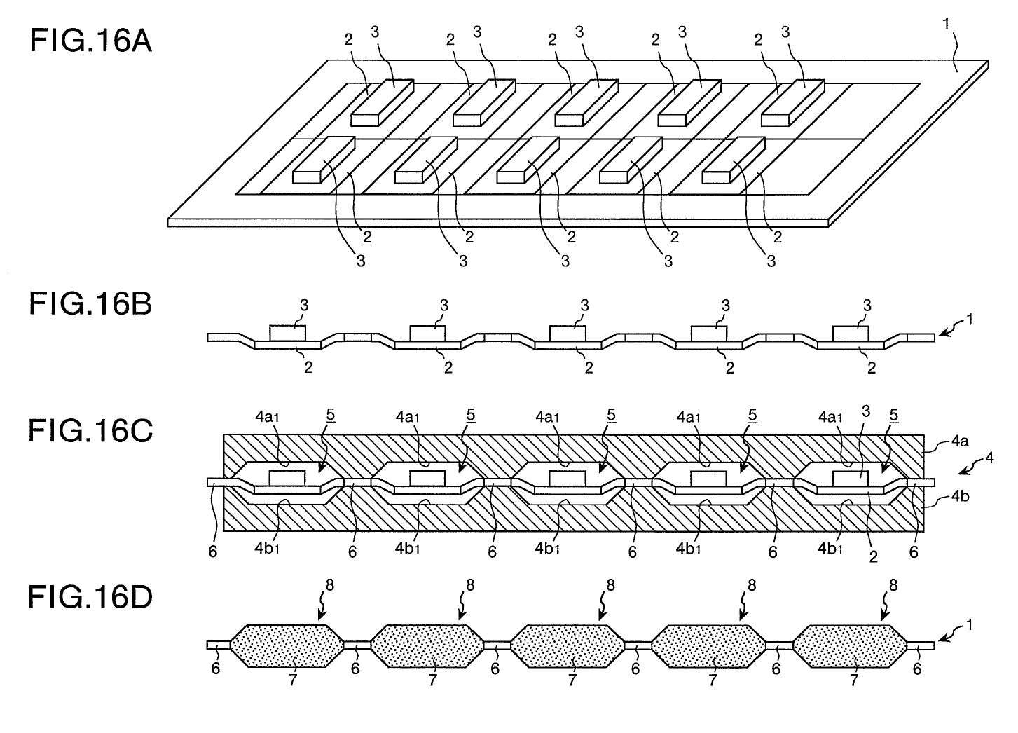

FIG. 15 sequentially shows a method of manufacturing the semiconductor device in the third embodiment according to the present invention. Similarly to the semiconductor devices shown in the first embodiment, semiconductor devices to be manufactured in the third embodiment are TSOP type semiconductor devices constituted so that semiconductor chips mounted on the die pad sections of a lead frame and inner lead sections are sealed with a resin and that the outer leads of the lead frame are extended to the outside of the sealing resin. As shown in FIG. 15A, a plurality of die pad sections 11 are provided horizontally and vertically and the inner lead sections 13 and the outer lead sections 14 are provided around the respective die pad sections 11 so as to constitute a plurality of semiconductor devices together, as in the case of the first embodiment.

As shown in FIG. 15A and FIG. 15B, first, the semiconductor chip 12 is mounted on the die pad section 11 on each semiconductor device constituent section 20 on the lead frame 10, the inner lead section 13 on the lead frame 10 is connected to the bonding pad (not shown) of each semiconductor chip 12 by a conductor such as a wire and spacers 80 are bonded to the both sides of the outer lead section 14 on each semiconductor device constituent section 20 of the lead frame 10 through bonding sheets 15, respectively.

Each of the spacers 80 applied herein has a cross-sectional surface of a rectangular cylinder shape and is made of a metal material or a resin material for which heat resistance to prevent the spacer 80 from being fused or lost when filled with a molten resin to be described later as in the case of the spacers 80 shown in the second embodiment. Each spacer 80 has preferably dimensions so that the total thickness of the spacers 80 bonded to the both sides of each outer lead section 14 through the bonding sheets 15 to be described later, respectively, is equal to the thickness of the sealing resin 41 on each semiconductor device 40 to be manufactured.

On the other hand, each bonding sheet 15 has one side of a sheet as a base material coated with an adhesive having removability from the lead frame 10 and the other side of the sheet as the base material coated with an adhesive having excellent adhesiveness. The bonding sheet 15 is bonded to the lead frame 10 through one side and bonded to the spacer 80 through the other side. As in the case of the first embodiment, heat resistance to prevent the sheet serving as the base material from being fused or lost when a molten resin to be described later is filled is secured for the sheet serving as the base material. To make the lead frame 10 hold the spacers 80, the spacers 80 may be bonded to the lead frame 10 by the bonding sheets 15 whether the spacers 80 are metal spacers or resin spacers. It is, therefore, possible to perform the operation quite easily compared with the second embodiment.

Next, in the same manner as the second embodiment, the lead frame 10 stated above is arranged in the cavity 31 of a metal mold 30, a sealing resin 41 in a molten state is filled into the cavity 31 of the metal mold 30 and separated from the metal mold 30 after the passage of a predetermined pressure maintaining and cooling period of time. The metal mold 30 applied herein has the same configuration as that of the metal mold 30 shown in the second embodiment. Namely, the metal mold 30 having an upper mold 30a and a lower mold 30b respectively provided with cavity constituent sections 30a₁ and 30b₁ which face each other and which can be opened and closed relative to each other is employed herein. The cavity constituent sections 30a₁ and 30b₁ are provided at the upper die 30a and the lower die 30b, respectively, as in the case of those in the second embodiment. Namely, each of the cavity constituent sections 30a₁ and 30b₁ has a width and a length to allow containing the die pad sections 11 on which the semiconductor chips 12 are mounted, the inner lead sections 13 and at least a part of the sections to which the bonding sheets 15 are bonded in all the semiconductor device constituent sections 20 provided on the lead frame 10 if the upper mold 30a and the lower mold 30b are closed relative to each other. In addition, the cavity constituent sections 30a₁ and 30b₁ are constituted to define only one cavity 31 having a height equal to the thickness of the sealing resin 41 on a semiconductor device 40 to be manufactured.

In the third embodiment, in the same manner as the second embodiment, the spacers 80 having a total thickness including the bonding sheets 15 which is equal to the thickness of the sealing resin 41 on a semiconductor device 40 to be manufactured, are fixedly attached to the both sides of each outer lead section 14 on the lead frame 10, respectively. Accordingly, if the upper mold 30a and the lower mold 30b are closed in a state in which the lead frame 10 is arranged in the cavity 31 of the metal mold 30, the outer surfaces of the spacers 80 are abutted on the inner wall surfaces of the cavity 31 to thereby support the outer lead sections 14 of the lead frame 10. As a result, even if the cavity 32 of the metal mold 30 is filled with the sealing resin 41 in a molten state, there is no fear that the outer lead sections 14 are vertically shifted in the cavity 31, thereby making it possible to seal the semiconductor chips 12 and the inner lead sections 13 on all the semiconductor device constituent sections 20 at the common positions of the sealing resin 41, respectively.

Thereafter, in the same manner as the second embodiment, support tapes 50 are bonded alternately on the surfaces of the sealing resin 41 to thereby fix the lead frame 10. In this state, kerfs 42 are sequentially formed on the both sides of the sealing resin 41 by the blade 60 of a cutting machine. The blade 60 of the cutting machine is not necessarily progressed along the edges of the spacers 80 fixedly attached to the lead frame 10. It suffices that the blade 60 is progressed along the outside shape of the sealing resin 41 to be constituted on the semiconductor device 40 and reaches at least the edges of the bonding sheets 15. The depth of each kerf 42 cut by the blade 60 is set not to reach the surface of the lead frame 10 as in the case of the second embodiment.

As a result, members located on the surface layer regions of the outer lead sections 14 of the lead frame 10 are separated from the sealing resin 41 of the semiconductor devices 40 (in the example shown, only the spacers 80 are separated) by the kerfs 42 formed on the both sides of the sealing resin 41. Accordingly, as in the case of the second embodiment, if removal tapes 70 are bonded to the both sides of the sealing resin 41, respectively and the removal tapes 70 thus bonded are removed from the sealing resin 41, then the spacers 80 (or spacers 80 and sealing resins 41′) as the members located on the surface layer regions of the outer lead sections 14 can be removed. Besides, by cutting off the outer lead sections of the adjacently provided semiconductor devices 40, it is possible to obtain desired semiconductor devices 40 sealed with the sealing resin 41 having the desired width and length and the desired outside shape.

According to the method of the third embodiment, as already stated above, by sealing even the outer lead sections 14 which do not require the sealing resin 41 with the sealing resin 41 and then removing the spacers 80 (or spacers 80 and sealing resins 41′) located on the surface layer regions of the outer lead sections 14, the width, length and outside shape of the sealing resin 41 on the semiconductor devices 40 are specified. It is, therefore, possible to use the common metal mold 30 even if semiconductor devices 40 different in the width, length and/or outside shape of the sealing resin 41 are to be manufactured. That is, even after the sealing resin 41 is separated from the common metal mold 30, it is possible to obtain semiconductor devices 40 sealed with the sealing resin 41 having a width and a length changed and a desired outside shape by forming kerfs 42 along the changed width and length or the outside shape of the sealing resin 41 and removing the spacers 80 (or spacers 80 and sealing resins 411) located on the surface layer regions of the outer lead sections 14. Consequently, according to the manufacturing method, even if the width, length and/or outside shape of the sealing resin 41 are changed, there is no need to design and manufacture a new metal mold 30, making it possible to promptly deal with such a change and to prevent the increase of manufacturing cost. Moreover, since there is no need to change the metal mold 30, no setup operation is required to continuously manufacture semiconductor devices different in the width, length and/or outside shape of the sealing resin 41, thereby making it possible to improve manufacturing efficiency.

Additionally, since the bonding sheets 15 having removability are simply interposed between the spacers 80 to be removed and each outer lead section 14, it is possible to easily perform the removal operation of the spacers 80. In the example shown in FIG. 15A and FIG. 15B, only the spacers 80 are removed. It is, however, sometimes necessary to remove not only the spacers 80 but also sealing resins 41′ depending on the positions and angles of the kerfs 42. In that case, however, since the spacers 80 and the bonding sheets 15 are interposed between the sealing resins 41′ to be removed and the outer lead sections 14 in advance, it is possible to prevent the outer lead sections 14 and the sealing resins 41′ from being fixedly coupled to each other when hardening the sealing resin 41, making it possible to facilitate the removal operation of the spacers 80 and the sealing resins 41′. In the third embodiment, since the quantity of the sealing resins 41 to be removed can be reduced (to zero in the example shown) by the presence of the spacers 80, it is possible to improve operation efficiency and to further reduce manufacturing cost.

Furthermore, the bonding sheets 15 having removability from the outer lead sections 14 are employed. Due to this, if the sealing resin 41 is filled into the metal mold 30, it is possible to prevent the positional errors of the bonding sheets 15 relative to the outer lead sections 14. If the spacers 80 (or spacers 80 and sealing resins 41) are removed, the bonding sheets 15 can be easily removed from the outer lead sections 14. It is, therefore, prevent the removal operation of the spacers 80 (or spacers 80 and sealing resins 41′) from becoming complex and to prevent the width, length and/or outside shape of the sealing resin 41 from becoming uneven on the semiconductor devices 40.

Moreover, the spacers 80 are constituted so that the total thickness of the spacers 80 and the bonding sheets 15 bonded to the both sides of each outer lead section 14, respectively, is equal to the thickness of the sealing resin 41 on the semiconductor device 40 to be manufactured. If the lead frame 10 is arranged in the cavity 31 of the metal mold 30, the individual outer surfaces of the spacers 80 are abutted on the inner wall surfaces of the cavity 31, respectively. Due to this, even if the cavity 31 of the metal mold 30 is filled with the sealing resin 41 in a molten state, there is no fear that the outer lead sections 14 are vertically shifted in the cavity 31. As a result, it is possible to seal the semiconductor chips 12 and the inner lead sections 13 on all the semiconductor device constituent sections 20 at the common positions of the sealing resin 41, respectively and to, therefore, uniform the various performances of the semiconductor devices 40 such as heat resistance, moisture resistance, impact resistance and pressure resistance.

In addition, since the bonding sheet 15 is interposed between the spacer 80 and the outer lead section 14 and the spacer 80 is bonded to the outer lead section 14 by the adhesive strength of the sheet 15, there is no need to employ welding means or bonding means such as an adhesive separately unlike the second embodiment, thereby making it possible to facilitate operations.

In the first to third embodiments, a plurality of semiconductor devices are constituted together, so that manufacturing efficiency can be improved. However, it is not always necessary to constitute a plurality of semiconductor devices together. For reference, if a plurality of semiconductor devices are constituted together, it is not necessary that the sealing resins of the respective semiconductor devices have the same width, length and/or outside shape.

Further, in the first to third embodiments, the TSOP type semiconductor device is shown as a semiconductor device by way of example. The other types of semiconductor devices are available if they includes parts sealed by a sealing resin and parts exposed to the outside of the sealing resin.

Furthermore, in the first to third embodiments, the kerfs are formed in the sealing resin by using the cutting machine and the unnecessary sealing resin is removed with the kerfs set as boundaries. The sealing resin maybe removed by the other methods. Besides, in the second and third embodiments, the spacers 80 are abutted on the inner wall surfaces of the cavity and the kerfs are provided along the edges of the spacers. Due to this, in the step of removing the members covering the surface layer regions which become the outer leads, only the spacers 80 are actually removed. The present invention is not, however, necessarily limited thereto. Namely, a spacer having a height with which the spacer is not abutted on the inner wall surface of the cavity may be employed and there is no need to provide kerfs along the edges of the spacers. In these cases, in the step of removing the members covering the surface layer regions which become the outer leads, the spacers and the sealing resins are removed. However, since the spacer is interposed between the sealing resin and the part which becomes the outer lead, the removal operation therefor is not complicated.

In the first to third embodiments, the removal members are fixedly attached to the parts which become the outer leads of the lead frame, thereby making it possible to facilitate the following removal operation. However, it is not always necessary to fixedly attach the removal members to the parts.

As stated so far, according to one aspect of the present invention, since the width, the length and/or the outside shape of the sealing resin on each semiconductor device can be changed according to the members to be removed, it is possible to manufacture semiconductor device different in the width, the length and/or the outside shape of the sealing resin by using the metal mold having a common cavity. As a result, there is no need to design and manufacture a new metal mold, making it possible to promptly deal with such a change and to prevent the increase of manufacturing cost. Moreover, no setup operation is required to continuously manufacture semiconductor devices different in the width, length and/or outside shape of the sealing resin, thereby making it possible to greatly improve manufacturing efficiency.

According to another aspect of the present invention, since the width, the length and/or the outside shape of the sealing resin on each semiconductor device can be changed according to the members to be removed, it is possible to manufacture semiconductor device different in the width, the length and/or the outside shape of the sealing resin by using the metal mold having a common cavity. As a result, there is no need to design and manufacture a new metal mold, making it possible to promptly deal with such a change and to prevent the increase of manufacturing cost. Moreover, no setup operation is required to continuously manufacture semiconductor devices different in the width, length and/or outside shape of the sealing resin, thereby making it possible to greatly improve manufacturing efficiency. Besides, even if the sealing resin is removed, since the removable members are interposed between the member to be removed and the section to become the outer lead in advance, it is possible to prevent the member to be removed and the section to become the outer lead from being fixedly coupled to each other, thereby making it possible to facilitate the sealing resin removal operation.

Furthermore, it is possible to prevent the positional error of the removable members relative to the section to become the outer lead if the sealing resin is filled into the metal mold and it is possible to easily remove the removable members from the section to become the outer lead if removing the member covering the section to become the outer lead. It is, therefore, possible to prevent the removal operation of the member from becoming complex and to prevent the width, length and/or outside shape of the sealing resin from becoming uneven on the semiconductor devices.

Moreover, even if the sealing resin is removed, the quantity of the sealing resin can be reduced by the presence of the spacers, thereby making it possible to improve operation efficiency and to further reduce manufacturing cost.

Furthermore, ven if the sealing resin is removed, the quantity of the sealing resin can be reduced by the presence of the spacers and the spacer removal operation becomes easier, thereby making it possible to further improve operation efficiency.

Moreover, it is possible to ensure preventing the positional shift of the lead frame if the sealing resin is filled into the metal mold. It is, therefore, possible to prevent the positions of the lead frame filled with the sealing resin in the semiconductor devices from becoming uneven and to uniform the various performances of the semiconductor devices such as heat resistance, moisture resistance, impact resistance and pressure resistance.

Furthermore, it is possible to simultaneously manufacture a plurality of semiconductor devices from one metal mold. Due to this, it is possible to improve manufacturing efficiency.

Moreover, it is possible to change the width, the length and/or the outside shape of the sealing resin according to the members to be removed. It is, therefore, possible to manufacture semiconductor devices different in the width, the length and/or the outside shape of the sealing resin by using the metal mold having a common cavity. As a result, there is no need to design and manufacture a new metal mold, making it possible to promptly deal with such a change and to prevent the increase of manufacturing cost. Moreover, no setup operation is required to continuously manufacture semiconductor devices different in the width, length and/or outside shape of the sealing resin, thereby making it possible to greatly improve manufacturing efficiency.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A method of manufacturing the semiconductor device comprising:
arranging at least a part of a portion of a lead frame that is to be sealed with a resin, and a portion that is to become an outer lead, respectively, in a cavity of a metal mold;
filling a sealing resin into the cavity of said metal mold, and hardening the sealing resin; and
removing a member covering a surface layer region of the section, to become the outer lead, of said lead frame.

2. The method of manufacturing the semiconductor device according to claim 1, wherein
a plurality of semiconductor device constituent sections are arranged in a common cavity of said metal mold on said lead frame.

3. A method of manufacturing the semiconductor device comprising:
fixedly attaching removable members to both sides of a section, to become an outer lead, of a lead frame;
arranging a section, to be sealed with a resin, of said lead frame including said removable members in a cavity of a metal mold;
filling a sealing resin into the cavity of said metal mold, and hardening the sealing resin;
forming a groove ranging from a surface of said sealing resin to edges of said removable members; and
removing a member covering the section to become said outer lead, with the portion in which said groove is formed set as a boundary.

4. The method of manufacturing the semiconductor device according to claim 3, wherein
bonding sheets having removability with respect to the section to become said outer lead are employed as said removable members.

5. The method of manufacturing the semiconductor device according to claim 3, wherein
spacers detachable from the section to become said outer lead are employed as said removable members.

6. The method of manufacturing the semiconductor device according to claim 3, wherein
spacers each having a removable bonding surface formed between each spacer and the section to become said outer lead, are employed as said removable members.

7. The method of manufacturing the semiconductor device according to claim 5, wherein
if said lead frame is arranged in the cavity of said metal mold, said spacers are abutted on inner wall surfaces of the cavity.

8. The method of manufacturing the semiconductor device according to claim 6, wherein
if said lead frame is arranged in the cavity of said metal mold, said spacers are abutted on inner wall surfaces of the cavity.

9. The method of manufacturing the semiconductor device according to claim 3, wherein
a plurality of semiconductor device constituent sections are arranged in a common cavity of said metal mold on said lead frame.

10. A semiconductor device manufactured by:
arranging at least a part of a portion of a lead frame that is to be sealed with a resin, and a portion that is to become an outer lead, respectively, in a cavity of a metal mold;
filling a sealing resin into the cavity of said metal mold, and hardening the sealing resin; and
removing a member covering a surface layer region of the section, to become the outer lead, of said lead frame.

11. A semiconductor device manufactured by:
fixedly attaching removable members to both sides of a section, to become an outer lead, of a lead frame;
arranging a section, to be sealed with a resin, of said lead frame including said removable members in a cavity of a metal mold;
filling a sealing resin into the cavity of said metal mold, and hardening the sealing resin;
forming a groove ranging from a surface of said sealing resin to edges of said removable members; and
removing a member covering the section to become said outer lead, with the portion in which said groove is formed set as a boundary.
